(19) United States
(12) Patent Application Publication
(10) Pub. No.: US 2026/0219328 A1
(43) Pub. Date: Jul. 30, 2026

(54) KIT AND METHOD FOR DETECTING THE ELECTRICAL LOAD OF A MOTOR-VEHICLE BATTERY WHEN THE MOTOR-VEHICLE IS INACTIVE AND IN A SLEEP STATE

(71) Applicant: Stellantis Europe S.p.A., Torino (IT)

(72) Inventor: Silvano BRUNO, Torino (IT)

(21) Appl. No.: 19/145,365

(22) PCT Filed: Dec. 28, 2023
(86) PCT No.: PCT/IB2023/063329

§ 371 Date: Jul. 2, 2025

(30) Foreign Application Priority Data
Jan. 4, 2023 (IT) 102023000000066

(51) Int. Cl. G01R 31/385; G01R 31/00; G01R 31/364

(52) U.S. Cl. CPC G01R 31/385; G01R 31/006; G01R 31/364

(57) ABSTRACT

The electrical load of a vehicle battery, when the vehicle is inactive and in a sleep condition, is measured using an ammeter. An electrical connector associated with a ground conductor connected to the battery's negative pole is removed from this pole and between this connector and this pole, a connection line is interposed, having two conductors connected in series by coupling a plug connector and a receptacle connector arranged at their ends. The ammeter has its two poles connected to the two conductors, after which the connection between the two conductors is interrupted by decoupling the plug receptacle connectors, so that the ammeter is connected in series between the negative pole and ground. The ammeter can therefore measure current supplied by the battery during the sleep condition, without the operation of connecting the ammeter involving a new disconnection of the battery from the vehicle's electrical circuit.

### FIELD OF THE INVENTION

The present invention concerns a kit and a method for detecting the electrical load of a motor-vehicle battery, when the motor-vehicle is inactive and in a sleep state.

### PRIOR ART

Modern motor-vehicles are equipped with one or more electronic control and processing units, with which there are associated one or more memories configured to implement a plurality of functions, including that of storing a plurality of data after the motor-vehicle engine has been turned off, in order to allow the motor-vehicle control system to prepare itself in a condition suitable for subsequent starting of the motor-vehicle engine. Just to give an example, the motor-vehicle control unit stores the angular position of the crankshaft when the engine is turned off. The data storage operation, in the engine off condition, requires energy consumption, as the vehicle's electronic control units remain active for a certain period after the engine is turned off, and then pass into a sleep state.

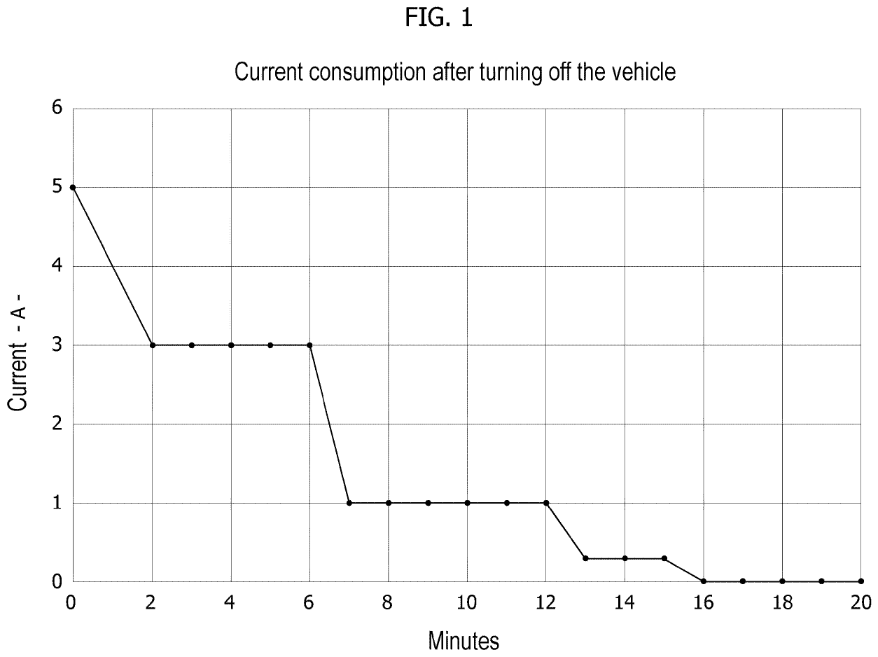

FIG. 1 of the attached drawings is a diagram that measures the electric current that the electric battery of the motor-vehicle must deliver after the engine is turned off (“key off”). As can be seen, the required electric current remains relatively high for several minutes after the engine is turned off, the variation in current over time being very variable depending on the type of motor-vehicle and its equipment.

From a diagnostic point of view, it becomes important to detect with good precision the value of the current required during the sleep state, corresponding to the energy consumption of the motor-vehicle when it is stationary and inactive. In the presence of malfunctions or problems related to design errors, this value can become excessively high and cause the state of charge of the battery to deteriorate rapidly. It is therefore current practice in the development of a new motor-vehicle model, and in the maintenance of a motor-vehicle, particularly following unwanted episodes of a loss of battery charge, to verify that the value of the current absorbed in the sleep state is contained within predetermined limits.

This check operation must be carried out paying attention to the maneuver to which the motor-vehicle is subjected before reaching the sleep state. The normal condition is represented by turning off the motor-vehicle using the key off. The execution of the operation of checking the current absorbed in the sleep state is however relatively critical, as it must be carried out avoiding an interruption of the connection of the battery with the electrical system of the motor-vehicle. An interruption of this connection is explained by the motor-vehicle control system as a battery detachment, which automatically causes the activation of a series of strategies. In particular, when the power supply is re-established, the motor-vehicle control units “wake up” causing an increase in power consumption, and then return to the sleep state after some time.

According to the prior art, the measurement of the current in the electrical circuit of the motor-vehicle can be carried out with an ammeter, which must be connected in series in the electrical circuit, or using a current clamp.

The measurement with an ammeter is the most precise method, but has some problems:
1) requires the execution of difficult operations, as the ammeter must be positioned in series with the circuit without causing interruption of the circuit itself, for the reasons already indicated above;
2) if the ammeter measures a value beyond its maximum scale value, it may incur irreversible damage (normally the ammeter is equipped with a protection fuse, for this very reason);
3) if it is necessary to carry out operations on the motor-vehicle (for example activating the centralized locking of the doors, starting the engine, operating a window regulator) it is necessary to disconnect the ammeter, as otherwise it would be damaged, which then forces the cycle to be repeated to insert the ammeter if a new measurement is needed.

The measurement with a current clamp is a less invasive method, it does not require operations on the cabling, as the current clamp can be connected and disconnected with very easy operations, but it presents a number of drawbacks:
1) the current clamp has poor precision for very small current values,
2) great attention must be paid to the positioning of the current clamp, as it is sensitive to magnetic fields, which can induce significant measurement errors,
3) the current clamp, if subjected to an off-scale current value, can present permanent magnetism phenomena which introduce measurement errors,
4) the current clamp is an expensive instrument.

There is therefore a need to prepare new equipment and a new method to carry out the operation of measuring the electrical load of the motor-vehicle battery in the workshop, when the motor-vehicle is inactive and the battery is in a sleep condition, which are simpler and easier to use than known systems and which at the same time guarantee high reliability of the measurement operation.

A method according to the preamble of claim 1 and a kit according to the preamble of claim 2 are known from document US 2016/231370 A1. This document shows a complex and expensive solution, using two pairs of dedicated cables to connect a current measuring instrument in series between the negative pole of the battery and the ground. The cables include a switch which when closed excludes the instrument and when open inserts the instrument into the connection in series between the negative pole of the battery and the ground.

Further solutions are described in the document “How you determine what is causing a parasitic drain on a car battery?”, Feb. 2, 2021 (2021 Feb. 2), XP093060495 and in the document “Proven techniques for battery drain diagnosis”, Sep. 30, 2014 (2014 Sep. 30), XP093060548.

### OBJECT OF THE INVENTION

It is therefore an object of the present invention to provide a kit and a method for detecting the current consumption of the electrical system of a motor-vehicle, when it is inactive, which can be implemented with simple and easy operations and which at the same time guarantee relatively high measurement precision.

A further purpose of the invention is to provide a kit of the type indicated above which can be used to measure any current of the motor-vehicle electrical system in any state of the vehicle.

A further object of the invention is to provide a kit and a method of the type indicated above which are simple and economical.

A further object of the invention is to provide a kit and a method of the type indicated above which can also be easily implemented on board the motor-vehicle, and even with the bonnet and trunk of the motor-vehicle in a closed condition.

A further object of the invention is to provide a kit and a method of the type indicated above which also allow maneuvers to be carried out on board the motor-vehicle (e.g. inserting loads, turning on lights, etc.) during measurement, protecting the measuring instrument from overcurrents.

A further object of the invention is to provide a kit of the type specified above which consists of standard, low-cost, commercially available elements.

### SUMMARY OF THE INVENTION

In order to achieve one or more of said objects, the invention has as its aim a method for detecting the electrical load of a motor-vehicle battery when the motor-vehicle is inactive, having the features indicated in claim 1.

Thanks to these features, the measurement operation can be carried out in a simple and easy way, guaranteeing the correct functioning of the current measuring instrument, which is an ammeter. In particular, the solution of the invention allows a drastic simplification and a notable economic saving compared to the solution known from document US 2016/231370 A1, since it simply provides two identical standard cables, which are connected or disconnected at their connectors adjacent to each other,

The invention also concerns the measurement kit used in the method described above.

The kit according to the invention is suitable for use in the workshop during maintenance interventions on the motor-vehicle, in particular following unwanted episodes of loss of charge of the motor-vehicle battery, as well as in analysis laboratories during the design and development of a new vehicle.

### DETAILED DESCRIPTION OF AN EXEMPLARY EMBODIMENT

The invention will be further described with reference to the attached drawings, provided by way of non-limiting example, in which:

FIG. 1 is a diagram, already explained above, of the variation over time in the current absorbed by the electrical system of a motor-vehicle after the engine is turned off, and

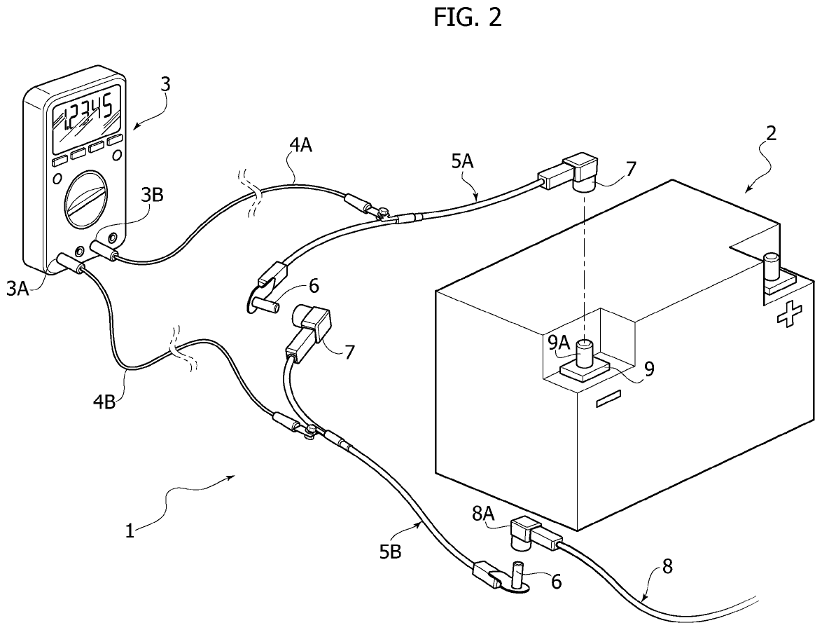

FIG. 2 is a schematic view of an embodiment of the kit according to the invention.

With reference to FIG. 2, the number 1 indicates as a whole a preferred embodiment of the kit according to the invention, which can be used to detect the electrical load of a motor-vehicle battery 2, when the motor-vehicle is inactive and in a sleep state. The kit 1 includes a current measuring instrument 3, specifically an ammeter of any known type, having two poles 3A, 3B, to which electrical cables 4A, 4B are associated, the function of which will be illustrated hereinafter.

The kit 1 further comprises a first electrical conductor 5A and a second electrical conductor 5B each having an electrical plug connector 6 of any known type at one of its first ends, and an electrical receptacle connector 7 of any known type, suitable for cooperating with an electrical plug connector of the type of connector 6, at its other end. The two electrical conductors 5A, 5B are insulated electrical conductors and the electrical connectors at the ends of each conductor are also insulated.

In the preferred embodiment, the two electrical conductors 5A, 5B are identical to each other and are of any standard type available on the market. Likewise, the electrical connectors 6, 7 are of any standard type available on the market, for example the type marketed under the trademark “Radsock” by the Amphenol company.

In FIG. 2, reference 8 indicates the electrical conductor conventionally connected to the negative pole 9 of the battery 2. In the illustrated embodiment, the negative pole 9 is equipped with a pin connector 9A, capable of cooperating with an associated receptacle connector 8A at the end of conductor 8.

In order to carry out the operation of measuring the electric current that the electric battery 2 must deliver during the sleep state, the two electric conductors 5A, 5B are connected in series with each other, coupling the connector 6 to one end of the first conductor 5A with connector 7 at one end of the second conductor 5B. In this way, the two conductors 5A, 5B form a single connection line.

The connector 8A of the conductor 8 usually associated with the negative pole 9 of the battery is removed from the pole 9 and is instead coupled with the connector 6 of the second electrical conductor 5B, while the connector 7 at one end of the first electrical conductor 5A is coupled with the pin connector 9A of the negative pole 9 of the battery. In this way the connection between the negative pole of the battery and the ground is re-established. In this condition, the two conductors 4A, 4B connected to the poles 3A, 3B of the ammeter 3 are respectively connected to the conductors 5A, 5B and the coupling between the two connectors 6, 7 of the two conductors 5A, 5B is interrupted (as illustrated in FIG. 2), so in this condition the ammeter 3 is connected in series between the negative pole 9 of the battery 2 and the ground. Ammeter 3 can then be activated to measure the current delivered by the battery during the sleep state.

As it is clear from the previous description, the measurement kit according to the invention consists of standard, extremely simple and low-cost components and can be implemented with easy and rapid operations, while at the same time guaranteeing high measurement precision.

Of course, notwithstanding the principle of the invention, the construction details and the embodiments may vary widely with respect to what has been described and illustrated purely by way of example, without thereby departing from the scope of the present invention.

1. A method for detecting an electrical load of a battery of a motor-vehicle when the motor-vehicle is inactive and in a sleep condition, said method comprising:
providing a current measuring instrument, having two poles for connection in series of said current measuring instrument to an electrical line to be subjected to measurement,
providing a first electrical conductor and a second electrical conductor, so as to form an electrical connection line including the first electrical conductor and the second electrical conductor connected in series with each other,
removing a connector associated with an electrical ground conductor connected to a negative pole of the battery from the negative pole of the battery,
connecting one end of said electrical connection line to the negative pole of the battery and the opposite end of said electrical connection line to the connector associated with the electrical ground conductor connected to the negative pole of the battery,
connecting the two poles of the current measuring instrument, by means of respective electric cables, to said first electric conductor and to said second electric conductor,
interrupting a connection between said first electrical conductor and said second electrical conductor connected in series, so that the current measuring instrument is connected in series between the negative pole of the battery and the ground, and
activating said current measuring instrument, to measure a current supplied by the battery during the sleep condition,
wherein:
said electrical connection line includes only the first electrical conductor and the second electrical conductor,
said first electrical conductor and said second electrical conductor are electrical conductors identical to each other and each have one end provided with a plug connector and the other end provided with a receptacle connector,
said electrical connection line consisting of the first electrical conductor and the second electrical conductor being formed by connecting the plug connector or the receptacle connector at one end of the first electrical conductor with the receptacle connector or the plug connector at one end of the second electrical conductor, and
said interruption of the connection between said first electrical conductor and said second electrical conductor, following which the current measuring instrument is connected in series between the negative pole of the battery and ground, is obtained by disconnecting the plug connector and the receptacle connector from each other at adjacent ends of the first electrical conductor and the second electrical conductor.

2. A kit for detecting an electrical load of a battery of a motor-vehicle when the motor-vehicle is inactive and in a sleep condition, said kit comprising:
a current measuring instrument, having two poles for connection in series of said current measuring instrument in an electrical line to be subjected to measurement,
a first electrical conductor and a second electrical conductor,
said current measuring instrument and said first electrical conductor and said second electrical conductor being configured to enable the following operations:
forming an electrical connection line including the first electrical conductor and the second electrical conductor connected in series with each other,
removing a connector associated with an electrical ground conductor connected to a negative pole of the battery from the negative pole of the battery,
connecting one end of said electrical connection line to the negative pole of the battery and connecting the opposite end of said electrical connection line to the connector associated with the electrical ground conductor connected to the negative pole of the battery,
connecting the two poles of the current measuring instrument, by means of respective electric cables, to said first electric conductor and to said second electric conductor,
interrupting a connection between said first electrical conductor and said second electrical conductor connected in series, so that the current measuring instrument is connected in series between the negative pole of the battery and ground,
activating said current measuring instrument to measure a current supplied by the battery during the sleep condition,
wherein:
said electrical connection line includes only the first electrical conductor and the second electrical conductor,
the first electrical conductor and the second electrical conductor are electrical conductors identical to each other and each have one end provided with a plug connector and the other end provided with a receptacle connector,
said electrical connection line consisting of the first electrical conductor and the second electrical conductor being formed by a connection between the plug connector or the receptacle connector at one end of the first electrical conductor and the receptacle connector or the plug connector at one end of the second electrical conductor, such that:
said interruption of the connection between said first electrical conductor and said second electrical conductor, following which the current measuring instrument is connected in series between the negative pole of the battery and ground, is obtained by disconnecting the plug connector and the receptacle connector from each other at adjacent ends of the first electrical conductor and the second electrical conductor.

3. (canceled)
